(19) United States
(12) Patent Application Publication
(10) Pub. No.: US 2012/0056223 A1
(43) Pub. Date: Mar. 8, 2012

(54) LED PACKAGE STRUCTURE AND PACKAGING METHOD THEREOF

(75) Inventors: Hsieh-Shen Hsieh, Taoyuan Hsien (TW); Chao-Min Chen, Taoyuan Hsien (TW); Li-Fan Lin, Taoyuan Hsien (TW); Shih-Peng Chen, Taoyuan Hsien (TW); Huang-Kun Chen, Taoyuan Hsien (TW)

(73) Assignee: DELTA ELECTRONICS, INC., Taoyuan Hsien (TW)

(21) Appl. No.: 13/103,986

(22) Filed: May 9, 2011

(30) Foreign Application Priority Data
Sep. 3, 2010 (TW) 099129804

(51) Int. Cl. H01L 33/50; H01L 33/48; H01L 33/62

(52) U.S. Cl. 257/98; 257/99; 438/27; 438/26; 257/E33.06; 257/E33.062; 257/E33.056

(57) ABSTRACT

A LED package structure includes a supporting substrate, a first electrically-conductive structure, a LED chip, an insulating layer and a second electrically-conductive structure. The supporting substrate includes a top surface, a bottom surface and a first channel. The first electrically-conductive structure is filled in the first channel and partially formed on the top and bottom surfaces of the supporting substrate. The LED chip is disposed over the supporting substrate. The insulating layer is formed over the supporting substrate and on bilateral sides of the LED chip. The insulating layer has a second channel corresponding to the first electrically-conductive structure. The second electrically-conductive structure is filled in the second channel and partially formed on the insulating layer, and connected with an electrode of the LED chip. The LED chip and the top and bottom surfaces of the supporting substrate are connected with each other through the first and second electrically-conductive structures.

### FIELD OF THE INVENTION

The present invention relates to a light emitting diode package structure and packaging method, and more particularly to a light emitting diode package structure and packaging method by employing a wireless interconnection technology.

### BACKGROUND OF THE INVENTION

Generally, a LED chip is packaged into a LED package structure in order to assure electrical connection between the LED chip and the substrate and protect the LED chip from damage by foreign attack (e.g. mechanical shock, heat or moisture). Depending on applications, shapes, heat-dissipating mechanisms and illuminating mechanisms, the LED package structures are classified into several types such as Lamp-LED, TOP-LED, Side-LED, SMD-LED, High-Power-LED, Flip Chip-LED, and the like.

Hereinafter, a process of manufacturing a SMD-LED (surface mount LED) package structure will be illustrated in more details. Firstly, a LED chip is fixed on a small substrate. Then, the LED chip is electrically connected with the substrate by a wire bonding process. Then, the substrate and the LED chip are covered by an encapsulant member, thereby producing a LED package structure. After the LED package structure is welded on a printed circuit board, a SMD-LED light source is produced. The SMD-LED package structure is compatible to a reflow soldering process while achieving desired luminance, view angle, evenness, reliability and uniformity.

However, in a case that the LED package structure is operated at high power, the heat-dissipating efficacy may affect the characteristics and the use life of the LED chip. If the heat accumulated within the LED package structure fails to be dissipated away, an elevated temperature at the contacts may impair the illuminating efficiency, shorten the wavelength of the light beam and reduce the use life. Generally, there are two approaches to solve these drawbacks. In a first approach, the illuminating efficiency of the LED chip is enhanced while reducing heat generation so that the contact temperature of the LED package structure is reduced. In a second approach, the configuration of the LED package structure is improved by using a high thermally-conductive encapsulant material to reduce the thermal resistance of the overall structure. In such way, the contact temperature is reduced, the reliability of the LED package structure is enhanced, and the use life is extended.

In the SMD-LED package structure, since the thermal conductivity of the encapsulant member is relatively low, it is difficult to dissipate away the heat that is within the package structure. The heat accumulation may deteriorate the performance, use life and reliability of the LED package structure. Moreover, since the difference between the thermal conductivities of the LED chip and the encapsulant member is very obvious, the stability and use life of the LED package structure are adversely affected. On the other hand, the glass transition temperature (Tg) of the resin of the encapsulant member is too low (about 120° C.). Once the SMD-LED package structure is soldered within a high-temperature oven at a temperature of 250° C.˜300° C., some defects may be generated in the SMD-LED package structure.

Conventionally, the light emitting diode is electrically connected with a substrate or a lead frame by a wire bonding process. FIG. 1 is a schematic cross-sectional view illustrating a conventional LED package structure. As shown in FIG. 1, the conventional LED package structure comprises a substrate 10, an insulating layer 11, a metallic layer 12, a LED chip 13 and an encapsulant member 15. The LED chip 13 is electrically connected with a substrate electrode 16 through a metallic wire 14 by a wire bonding process. For performing the wire bonding process, both terminals of a gold wire or aluminum wire having a diameter of 25 μm are respectively connected to the LED chip 13 and the substrate (or lead frame) via a thermo-compression bonding technology, an ultrasonic bonding technology or a thermosonic bonding technology. Generally, the thermosonic bonding technology is widely adopted by the LED manufacturers because the welding temperature is about 150° C. and the welding time of a single soldering point is about 20 ms. However, since the adhesion of the wire to the substrate electrode is possibly insufficient or the wire is possibly broken, the reliability of the conventional LED package structure is impaired.

Therefore, there is a need of providing a LED package structure and a manufacturing process thereof so as to obviate the drawbacks encountered from the prior art.

### SUMMARY OF THE INVENTION

The present invention provides a LED package structure and a process of manufacturing the LED package structure by wireless interconnection, thereby increasing the component reliability and avoiding the problem of causing insufficient adhesion and wire damage of the conventional wire bonding process.

In accordance with an aspect of the present invention, there is provided a LED package structure. The LED package structure includes a supporting substrate, at least one first electrically-conductive structure, a LED chip, an insulating layer and at least one second electrically-conductive structure. The supporting substrate includes a top surface, a bottom surface and at least one first channel. The first electrically-conductive structure is filled in the first channel and partially formed on the top surface and the bottom surface of the supporting substrate. The LED chip is disposed over the supporting substrate. The insulating layer is formed over the supporting substrate and on bilateral sides of the LED chip, wherein the insulating layer has at least one second channel corresponding to the first electrically-conductive structure. The second electrically-conductive structure is filled in the second channel and partially formed on the insulating layer, and connected with an electrode of the LED chip. The LED chip and the top surface and the bottom surface of the supporting substrate are electrically connected with each other through the first electrically-conductive structure and the second electrically-conductive structure.

In accordance with another aspect of the present invention, there is provided a LED package structure. The LED package structure includes a supporting substrate, at least one first electrically-conductive structure, a LED chip, an insulating layer and at least one second electrically-conductive structure. The supporting substrate has a top surface and a bottom surface, wherein the supporting substrate includes a first channel and a concave structure. The first electrically-conductive structure is filled in the first channel and partially formed on the top surface and the bottom surface of the supporting substrate. The LED chip is accommodated within the concave structure. The insulating layer is formed over the supporting substrate and the LED chip. The insulating layer has at least two second channels. The second channels are corresponding to an electrode of the LED chip and the first electrically-conductive structure, respectively. The second electrically-conductive structure is filled in the second channels and partially formed on the insulating layer, and connected with the electrode of the LED chip and the first electrically-conductive structure. The LED chip and the top surface and the bottom surface of the supporting substrate are electrically connected with each other through the first electrically-conductive structure and the second electrically-conductive structure.

In accordance with another aspect of the present invention, a LED packaging method is provided. The LED packaging method includes steps of: providing a supporting substrate comprising a top surface and a bottom surface; forming at least one first channel in the supporting substrate; forming at least one first electrically-conductive structure in the first channel and partially on the top surface and the bottom surface of the supporting substrate so as to electrically connect the top surface and the bottom surface of the supporting substrate; disposing a LED chip over the supporting substrate; forming an insulating layer over the supporting substrate and on bilateral sides of the LED chip, wherein the insulating layer has at least one second channel corresponding to the first electrically-conductive structure; and forming at least one second electrically-conductive structure in the second channel and partially on the insulating layer so as to connect with an electrode of the LED chip, wherein the LED chip and the top surface of the supporting substrate are electrically connected with each other through the second electrically-conductive structure.

In accordance with another aspect of the present invention, a LED packaging method is provided. The LED packaging method includes steps of: providing a supporting substrate comprising a top surface and a bottom surface; forming at least one first channel and a concave structure in the supporting substrate; forming at least one first electrically-conductive structure in said first channel and partially on said top surface and said bottom surface of said supporting substrate so as to electrically connect said top surface and said bottom surface of said supporting substrate; disposing a LED chip within the concave structure of the supporting substrate; forming an insulating layer over the supporting substrate and the LED chip and forming at least two second channels in the insulating layer, wherein each second channel is corresponding to an electrode of the LED chip and the first electrically-conductive structure; and forming at least one second electrically-conductive structure in the second channels and partially on the insulating layer so as to connect with the electrode of the LED chip and the first electrically-conductive structure.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating a conventional LED package structure;

FIGS. 2A˜2S schematically illustrate a method of manufacturing a LED package structure according to a first embodiment of the present invention;

FIGS. 3A and 3B schematically illustrate a process of forming the insulating layer by capillary injection or vacuum suction;

FIG. 4 schematically illustrates a process of forming the insulating layer by stencil printing;

FIG. 5 is a schematic cross-sectional view illustrating a variation example of the LED package structure of FIG. 2S;

FIG. 6 is a schematic cross-sectional view illustrating another variation example of the LED package structure of FIG. 2S;

FIGS. 7A˜7S schematically illustrate a method of manufacturing a LED package structure according to a second embodiment of the present invention;

FIGS. 8A˜8G schematically illustrate a method of manufacturing a LED package structure according to a third embodiment of the present invention;

FIG. 9 is a schematic cross-sectional view illustrating a variation example of the LED package structure of FIG. 8G; and

FIG. 10 is a schematic cross-sectional view illustrating another variation example of the LED package structure of FIG. 8G.

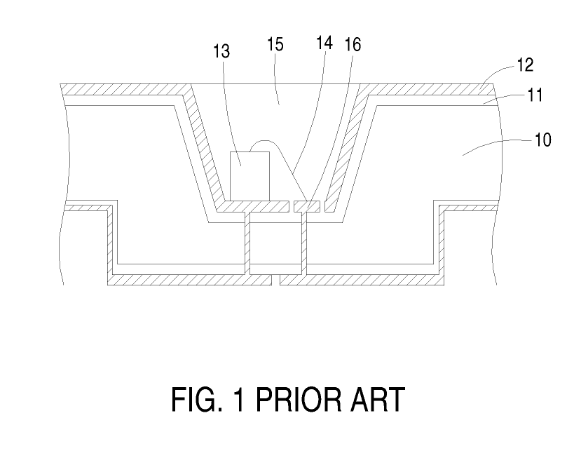

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

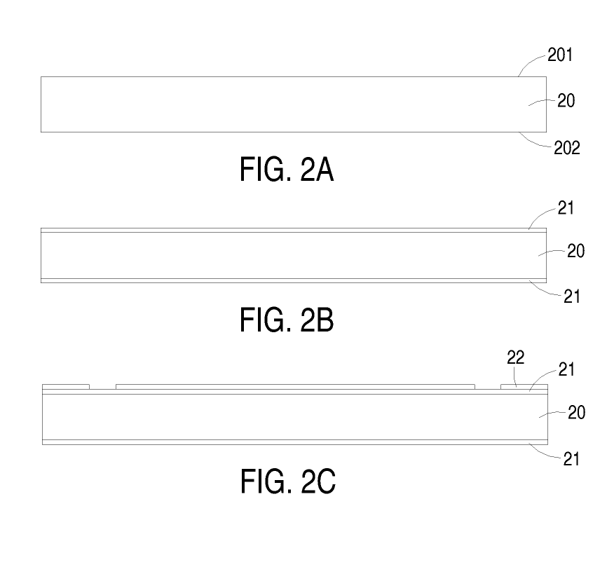

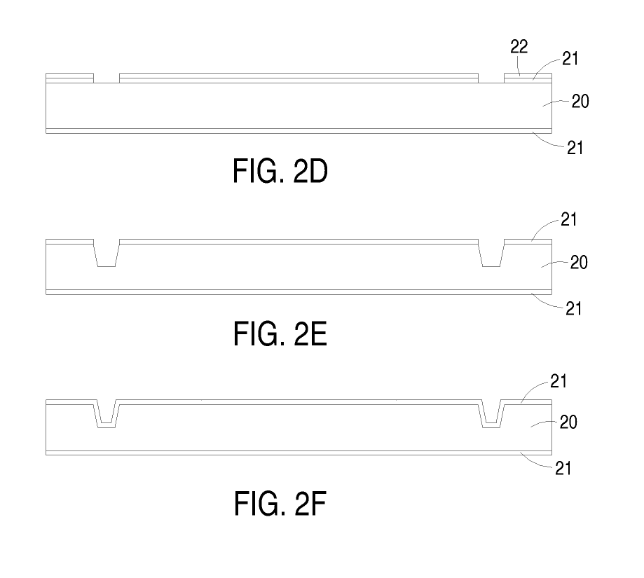

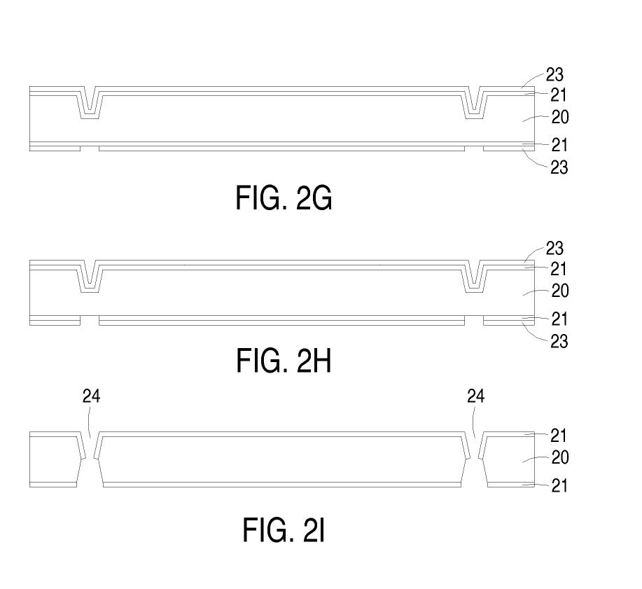

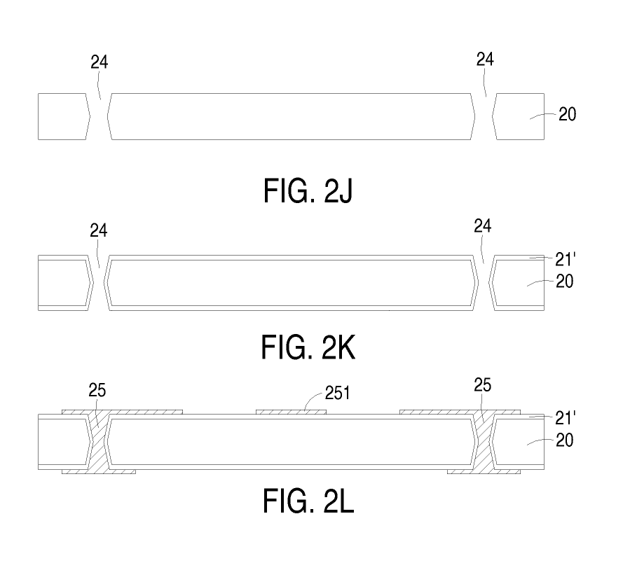

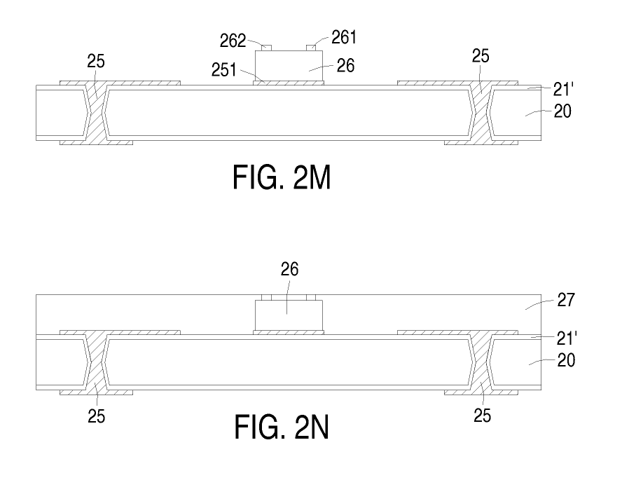

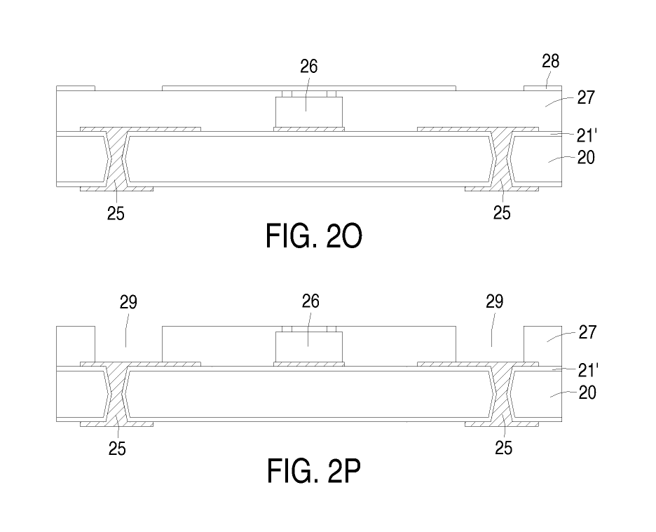

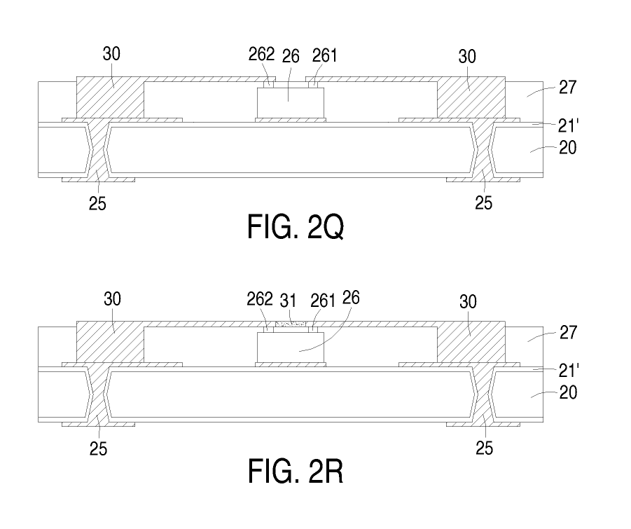

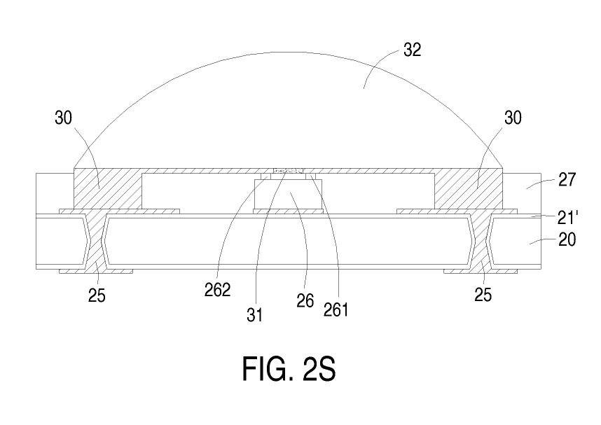

FIGS. 2A˜2S schematically illustrate a method of manufacturing a LED package structure according to a first embodiment of the present invention. Firstly, as shown in FIG. 2A, a supporting substrate 20 includes a top surface 201 and a bottom surface 202. The supporting substrate 20 is, for example, a silicon wafer. After a heat treatment is performed, the silicon dioxide layers are formed on the top surface 201 and the bottom surface 202 of the silicon wafer to serve as the etching stop layers 21 (see FIG. 2B). In comparison with the conventional metallic lead frame, the surface of the silicon wafer is smoother and suitable for performing a eutectic bonding process. Moreover, the silicon wafer has some additional benefits such as high thermal conductivity, high melting point and low mechanical stress. In addition, the thermal expansion coefficient of the silicon wafer is similar to that of the optoelectronic semiconductor.

The supporting substrate 20 is not limited to the silicon wafer. In some embodiments, the supporting substrate 20 may be a ceramic substrate, a sapphire substrate, a metallic substrate, a glass substrate or a plastic substrate. Moreover, the etching stop layers 21 are not limited to the silicon dioxide layers. In some embodiments, the etching stop layers 21 are made of silicon nitride, photoresist, metallic material, polymeric material or benzocyclobutene (BCB).

Then, as shown in FIG. 2C, a photoresist layer 22 is formed on the top surface 201 of the supporting substrate 20, and a photolithography process is performed to form a pattern in the photoresist layer 22. Then, the etching stop layer 21 uncovered by the photoresist layer 22 is removed by a wet etching process, a dry etching process, a laser drilling process or a mechanical drilling process, thereby forming the resulting structure of FIG. 2D. Then, as shown in FIG. 2E, the photoresist layer 22 is removed to form at least one recess in the supporting substrate 20. For example, the recess is formed by a wet etching process, wherein a potassium hydroxide (KOH) solution is used as an etchant solution. Alternatively, the recess may be formed by a dry etching process, a laser drilling process or a mechanical drilling process.

Then, a heat treatment is performed to form an etching stop layer 21 on the surface of the recess (see FIG. 2F). For example, the etching stop layer 21 is a silicon dioxide layer. In some embodiments, the etching stop layers 21 are made of silicon nitride, photoresist, metallic material, polymeric material or benzocyclobutene (BCB). Alternatively, the step of forming the etching stop layer 21 on the surface of the recess (see FIG. 2F) may be omitted.

Then, photoresist layers 23 are respectively formed at the top and bottom sides of the supporting substrate 20, and a photolithography process is performed to form a pattern in the photoresist layers 23 (see FIG. 2G). Then, the etching stop layer 21 uncovered by the photoresist layer 23 is removed by a wet etching process, a dry etching process, a laser drilling process or a mechanical drilling process, thereby forming the resulting structure of FIG. 2H. Then, the photoresist layers 23 are removed, and the supporting substrate 20 is etched or drilled by a wet etching process, a dry etching process, a laser drilling process or a mechanical drilling process, thereby forming at least one first channel 24 (see FIG. 2I). In this embodiment, the first channel 24 is formed in the supporting substrate 20 by the steps of FIGS. 2E˜2I in a two-stage manner. Alternatively, the first channel 24 may be formed in the supporting substrate 20 in a single-stage manner.

Then, a heat treatment is performed to form insulating layers 21′ (e.g. silicon dioxide layers) on the sidewall of the first channel 24 (see FIG. 2K). The insulating layers 21′ can be used as etching stop layers. Whereas, in a case that the etching stop layers 21 as shown in FIG. 2I are not made of silicon dioxide or silicon nitride, after the etching stop layers 21 are removed (see FIG. 2J), insulating layers 21′ are formed the top surface 201 and the bottom surface 202 of the supporting substrate 20 and the sidewall of the first channel 24 (see FIG. 2K). The insulating layers 21′ are made of silicon dioxide, silicon nitride, photoresist, metallic material, polymeric material or benzocyclobutene (BCB).

Then, as shown in FIG. 2L, a first electrically-conductive structure 25 is filled in the first channel 24 and partially formed on the top surface 201 and the bottom surface 202 of the supporting substrate 20 by physical vapor deposition (PVD), plating or stencil printing. In addition, the first electrically-conductive structure 25 further comprises a metallic base layer 251 for sequent die-bonding process. The first electrically-conductive structure 25 is made of metallic material for electrically connecting the top surface 201 of the supporting substrate 20 with the bottom surface 202 of the supporting substrate 20.

Then, a die-bonding process is performed. As shown in FIG. 2M, at least one LED chip 26 is placed and fixed on the metallic base layer 251 overlying the supporting substrate 20. In this embodiment, the LED chip 26 includes electrodes 261 and 262. The LED chip 26 can emit light whose wavelength is ranged from 200 nm to 800 nm. The number of the LED chip 26 can be varied according to the practical requirements. For providing a good bonding strength, the LED chip 26 is die-bonded on the metallic base layer 251 through silver paste, solder paste, polymeric material or silicone or by a eutectic bonding process.

Then, as shown in FIG. 2N, an insulating layer 27 is formed over the supporting substrate 20 and on bilateral sides of the LED chip 26. The surface of the insulating layer 27 is flat. In addition, the surface of the insulating layer 27 is substantially at the same level as the LED chip 26 so that the electrodes 261 and 262 are exposed. In other words, the insulating layer 27 and the LED chip 26 are substantially coplanar. The insulating layer 27 is made of polymeric material, silicone, silicon dioxide, photoresist, benzocyclobutene (BCB) or epoxy resin. In some embodiment, the insulating layer 27 is a planarization structure formed by capillary injection, vacuum suction or stencil printing, which will be illustrated later.

Then, as shown in FIG. 2O, a photoresist layer 28 is formed on the insulating layer 27, and a photolithography process is performed to form a pattern in the photoresist layer 28. Then, the insulating layer 27 uncovered by the photoresist layer 28 is removed by a wet etching process, a dry etching process, a laser drilling process or a mechanical drilling process. After removing the photoresist layer 28, at least one second channel 29 is formed (see FIG. 2P), wherein the second channel 29 is aligned with the first electrically-conductive structure 25. Then, as shown in FIG. 2Q, a second electrically-conductive structure 30 is filled in the second channel 29 and partially formed on the top surface of the insulating layer 27 by physical vapor deposition (PVD) process, plating or stencil printing. The second electrically-conductive structure 30 is extended from the second channel 29 to the LED chip 26. In addition, the second electrically-conductive structure 30 is connected with the electrodes 261 and 262 of the LED chip 26. The second electrically-conductive structure 30 is made of electrically-conductive material (e.g. metallic material) for electrically connecting the electrodes 261 and 262 with the top surface 201 of the supporting substrate 20.

Then, as shown in FIG. 2R, a light conversion layer 31 is formed on the top surface of the LED chip 26 for modulating the wavelength of the light emitted from the LED chip 26, thereby producing mixed light. An example of the light conversion layer 31 is a phosphor powder layer, a semiconductor quantum well or a quantum dot layer. The light conversion layer 31 may be formed by a dispensing process, a spraying process, a bonding process or a press molding process.

Afterward, as shown in FIG. 2S, a light-transmissible member 32 is formed over the LED chip 26 and the second electrically-conductive structure 30. In this embodiment, the light-transmissible member 32 is a patterned encapsulant member for covering and protecting the LED chip 26 from moisture and foreign article. In addition, the light-transmissible member 32 can be used for increasing the luminance and changing the light profile. The light-transmissible member 32 is made of silicone, polymeric material, epoxy resin, silicon dioxide or glass. The light-transmissible member 32 has a semi-spherical, a cylindrical shape or any other shape. In addition, the surface of the light-transmissible member 32 is curvy, planar or concave.

The light-transmissible member 32 can be produced by molding silicone, polymeric material, epoxy resin, silicon dioxide or glass, or dispensing silicone, polymeric material, epoxy resin, silicon dioxide or glass. Optionally, a barrier layer is formed on the periphery of the LED package structure before the light-transmissible member 32 is produced, and then the light-transmissible member 32 is formed between the barrier layer and the LED package structure by a molding process or a dispensing process.

In the above embodiment, the light conversion layer 31 is formed on the top surface of the LED chip 26. Alternatively, the light conversion layer 31 can be formed on the surface of the light-transmissible member 32 or formed in the light-transmissible member 32. For example, after phosphor powder is added to the host material of the light-transmissible member 32, the light-transmissible member 32 with the function of the light conversion layer is formed in the LED package structure.

From the above discussion, the LED package structure of the first embodiment includes a supporting substrate 20, a first electrically-conductive structure 25, a LED chip 26, an insulating layer 27, a second electrically-conductive structure 30 and a light-transmissible member 32 (see FIG. 2S). The supporting substrate 20 has a first channel 24 (see FIG. 2K). The first electrically-conductive structure 25 is formed in the first channel 24. The LED chip 26 is disposed over the supporting substrate 20. The insulating layer 27 is formed over the supporting substrate 20 and on bilateral sides of the LED chip 26. In addition, the insulating layer 27 has a second channel 29 (see FIG. 2P) corresponding to the first electrically-conductive structure 25. In addition, the second electrically-conductive structure 30 is filled in the second channel 29 and partially formed on the top surface of the insulating layer 27. In addition, the second electrically-conductive structure 30 is connected with the electrodes 261 and 262 of the LED chip 26. Through the first electrically-conductive structure 25 and the second electrically-conductive structure 30, the LED chip 26 and the top surface 201 and the bottom surface 202 of the supporting substrate 20 are electrically connected with each other. The light-transmissible member 32 is formed over the LED chip 26 and the second electrically-conductive structure 30 for covering and protecting the LED chip 26.

An example of the supporting substrate 20 is a silicon wafer. In comparison with the surface of the conventional metallic lead frame (or circuit board), the surface of the silicon wafer is smoother and suitable for performing a eutectic bonding process. Moreover, the silicon wafer has some additional benefits such as high thermal conductivity, high melting point and low mechanical stress. In addition, the electrodes 261 and 262 of the LED chip 26 and the top surface 201 of the supporting substrate 20 are electrically connected with each other by an overlay technique. Firstly, by capillary injection, vacuum suction or stencil printing, the insulating layer 27 is formed on bilateral sides of the LED chip 26. Then, the second channel 29 is formed in the insulating layer 27. Then, the second electrically-conductive structure 30 is filled in the second channel 29 and partially formed on the top surface of the insulating layer 27 by physical vapor deposition (PVD), plating or stencil printing. In such way, the electrical connection is achieved. In comparison to the conventional wire bonding process, the electrically-conductive structure produced by the wireless interconnection process is thicker and more reliable, and capable of withstanding higher mechanical stress. Consequently, the drawbacks encountered from the conventional wire bonding process (e.g. insufficient adhesion, broken wire or impaired reliability) will be obviated. Moreover, since the second electrically-conductive structure 30 is not attached on the sidewall of the LED chip 26, the light extraction efficiency of the LED chip 26 is not adversely affected.

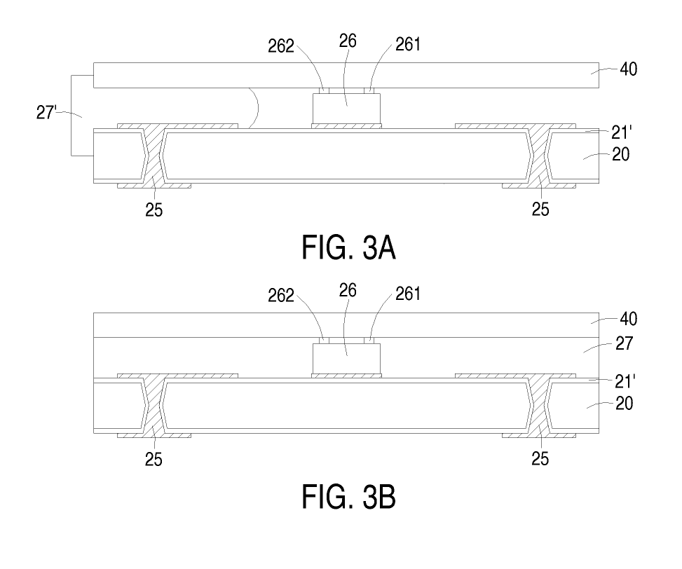

FIGS. 3A and 3B schematically illustrate a process of forming the insulating layer by capillary injection or vacuum suction. After the die-bonding process is performed on the LED chip 26 (see FIG. 2M), a slab 40 is formed over the LED chip 26. Then, an insulating material 27′ (e.g. a polymeric material or silicone) is filled into the space between the slab 40 and the supporting substrate 20 by capillary injection or vacuum suction (see FIG. 3A). Until the space between the slab 40 and the supporting substrate 20 is full of the insulating material 27′, the slab 40 is removed to result in the structure of FIG. 2N. In such way, the insulating layer 27 is formed on bilateral sides of the LED chip 26, and the second electrically-conductive structure 30 is formed on the surface of the insulating layer 27 and electrically connected with the electrodes 261 and 262 of the LED chip 26.

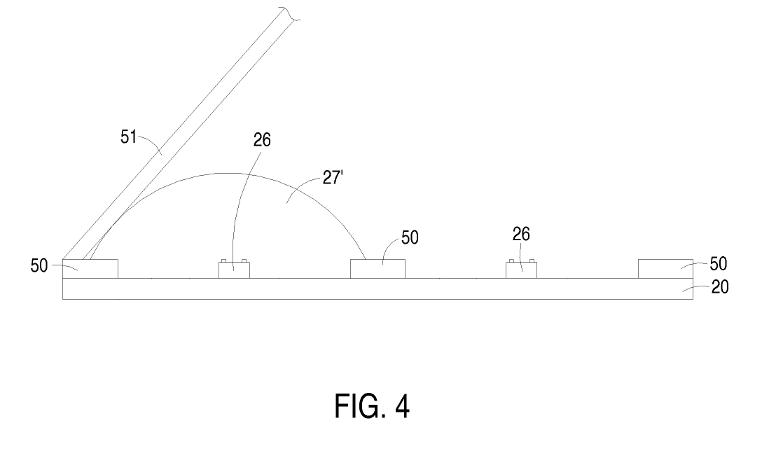

FIG. 4 schematically illustrates a process of forming the insulating layer by stencil printing. For clarification, some of the detailed configurations of the supporting substrate are omitted. After the die-bonding process is performed on the LED chip 26, a stencil 50 is arranged on the supporting substrate 20 to enclose bilateral sides of the LED chip 26. The top surface of the stencil 50 and the top surface of the LED chip 26 are substantially at the same level. Then, an insulating material 27′ (e.g. a polymeric material or silicone) is placed on the supporting substrate 20. Then, the insulating material 27′ is pressed by a squeegee 51 so that the insulating material 27′ is filled into the space between the LED chip 26 and the stencil 50. Consequently, a flat insulating layer 27 is produced. Then, the stencil 50 is removed to result in the structure of FIG. 2N. In such way, the insulating layer 27 is formed on bilateral sides of the LED chip 26, and the second electrically-conductive structure 30 is formed on the surface of the insulating layer 27 and electrically connected with the electrodes 261 and 262 of the LED chip 26.

Moreover, the LED package structure of the present invention has reduced layout area. By means of the semiconducting process, the manufacturing process of the present invention is advantage for producing LED package structure in a batchwise manner. In addition, the above process of forming the insulating layer is also suitable for mass production of the LED package structure. For example, by the stencil printing process, the insulating layers for plural LED chips can be simultaneously formed. Similarly, the sequent processes of forming the electrically-conductive structures can be performed by the semiconducting process. In comparison to the conventional wire bonding process, it is not necessary to connect the LED chips with the substrate one by one. Consequently, the drawbacks encountered from the conventional wire bonding process (e.g. insufficient adhesion or impaired reliability) will be obviated.

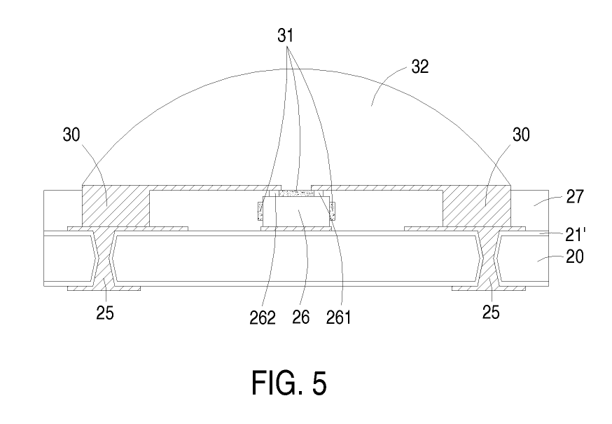

FIG. 5 is a schematic cross-sectional view illustrating a variation example of the LED package structure of FIG. 2S. In comparison with FIG. 2S, the light conversion layer 31 of the LED package structure of FIG. 5 is distinguished. After the die-bonding process is performed, the light conversion layer 31 is formed on the top surface and sidewalls of the LED chip 26. Then, the sequent steps of forming the insulating layer 27, the second electrically-conductive structure 30 and the light-transmissible member 32 are similar to those described in FIG. 2, and are not redundantly described herein.

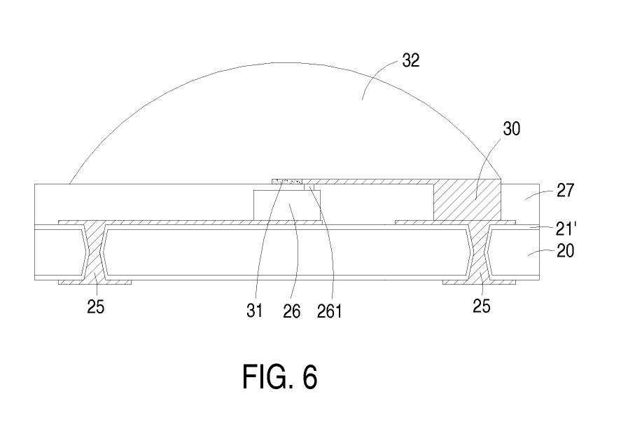

FIG. 6 is a schematic cross-sectional view illustrating another variation example of the LED package structure of FIG. 2S. In the LED package structure of FIG. 6, the LED chip 26 is a vertical type LED chip. One electrode 261 is formed on the top surface of the LED chip 26; and the other electrode (not shown) is formed on the bottom surface of the LED chip 26. In this embodiment, the first electrically-conductive structure 25 is extended to the bottom surface of the LED chip 26 so that the electrode on the bottom surface of the LED chip 26 is electrically connected with the first electrically-conductive structure 25. The electrode 261 on the top surface of the LED chip 26 is also electrically connected with the second electrically-conductive structure 30.

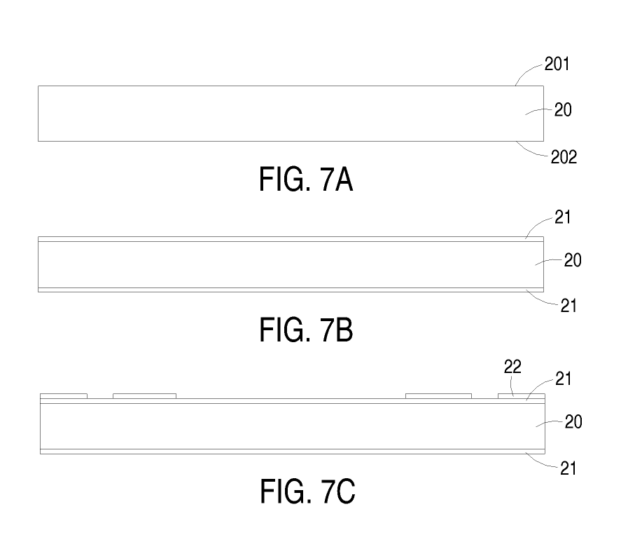

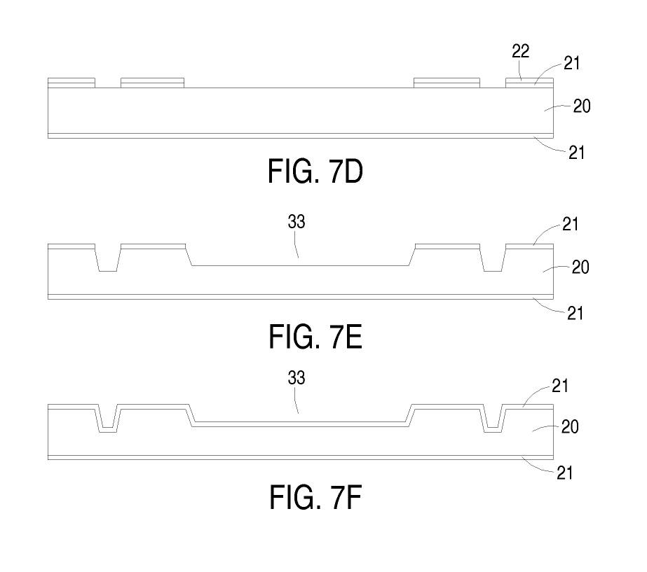

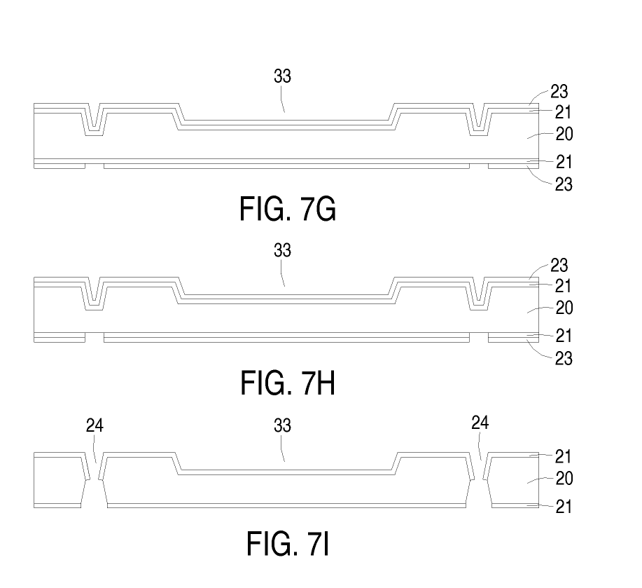

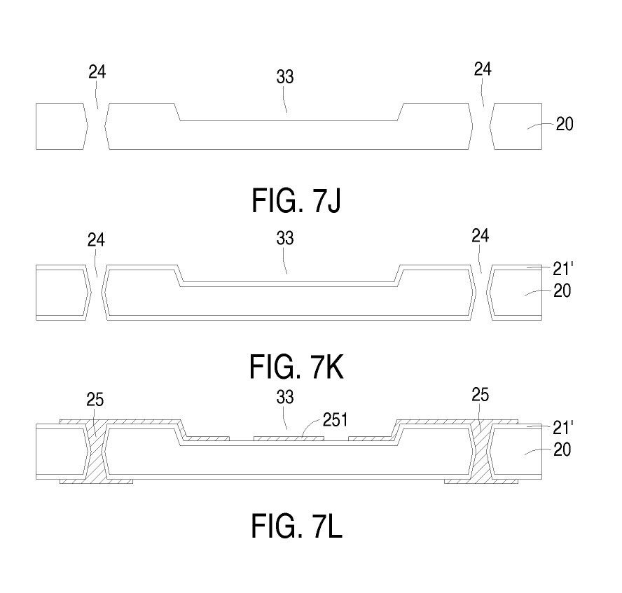

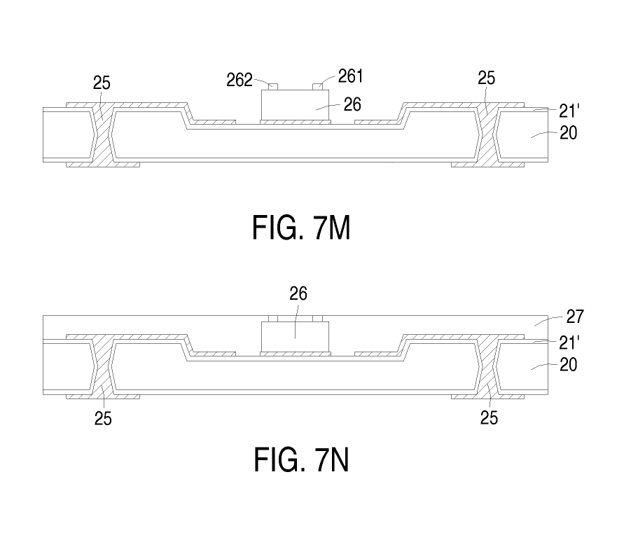

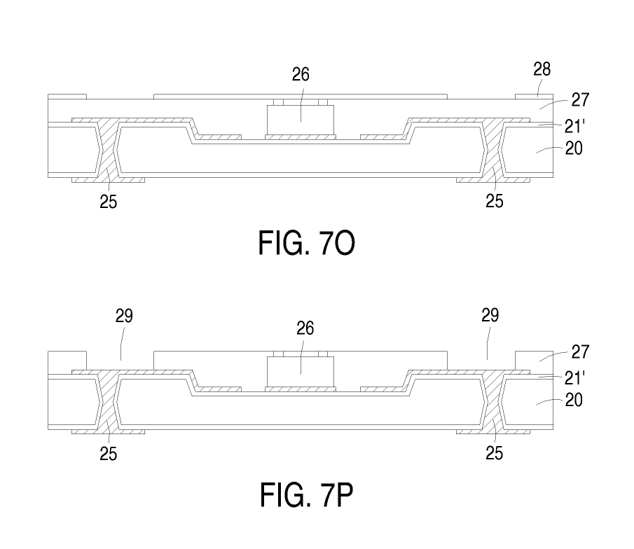

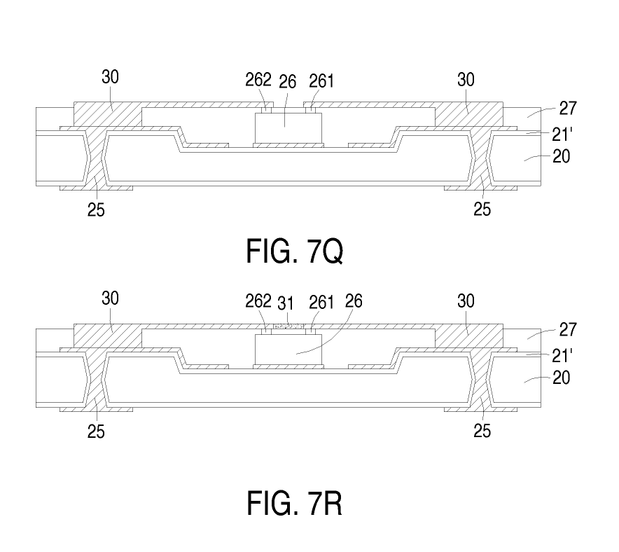

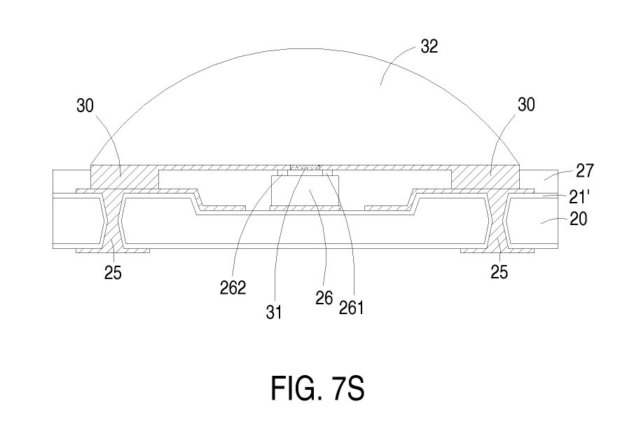

FIGS. 7A˜7S schematically illustrate a method of manufacturing a LED package structure according to a second embodiment of the present invention. The configuration of the resulting LED package structure is shown in FIG. 7S. Except that the supporting substrate 20 further comprises a concave structure 33 (see FIG. 7E) and the LED chip 26 is accommodated and fixed within the concave structure 33 (see FIG. 7M), the steps of manufacturing the LED package structure of FIG. 7S are similar to those of FIG. 2, and are not redundantly described herein. Moreover, the first electrically-conductive structure 25 is selectively formed on a portion of the surface of the concave structure 33 (see FIG. 7L), or only formed in the first channel 24 and the supporting substrate 20 between the first channel 24 and the concave structure 33.

From the above discussion, the LED package structure of the second embodiment includes a supporting substrate 20, a first electrically-conductive structure 25, a LED chip 26, an insulating layer 27, a second electrically-conductive structure 30 and a light-transmissible member 32 (see FIG. 7S). The supporting substrate 20 has a first channel 24 (see FIG. 7K). The first electrically-conductive structure 25 is formed in the first channel 24. The LED chip 26 is accommodated and fixed within the concave structure 33. The insulating layer 27 is formed over the supporting substrate 20 and on bilateral sides of the LED chip 26. In addition, the insulating layer 27 has a second channel 29 (see FIG. 7P) corresponding to the first electrically-conductive structure 25. The second electrically-conductive structure 30 is filled in the second channel 29 and partially formed on the top surface of the insulating layer 27. In addition, the second electrically-conductive structure 30 is connected with the electrodes 261 and 262 of the LED chip 26. Through the first electrically-conductive structure 25 and the second electrically-conductive structure 30, the LED chip 26 and the top surface 201 and the bottom surface 202 of the supporting substrate 20 are electrically connected with each other. The light-transmissible member 32 is formed over the LED chip 26 and the second electrically-conductive structure 30 for covering and protecting the LED chip 26.

An example of the supporting substrate 20 is a silicon wafer. In comparison with the surface of the conventional metallic lead frame (or circuit board), the surface of the silicon wafer is smoother and suitable for performing a eutectic bonding process. Moreover, the silicon wafer has some additional benefits such as high thermal conductivity, high melting point and low mechanical stress. In addition, the electrodes 261 and 262 of the LED chip 26 and the top surface 201 of the supporting substrate 20 are electrically connected with each other by an overlay technique. Firstly, by capillary injection, vacuum suction or stencil printing, the insulating layer 27 is formed on bilateral sides of the LED chip 26. Then, the second channel 29 is formed in the insulating layer 27. Then, the second electrically-conductive structure 30 is filled in the second channel 29 and partially formed on the top surface of the insulating layer 27 by physical vapor deposition (PVD), plating or stencil printing. In such way, the electrical connection is achieved. In comparison to the conventional wire bonding process, the electrically-conductive structure produced by the wireless interconnection process is thicker and more reliable, and capable of withstanding higher mechanical stress. Consequently, the drawbacks encountered from the conventional wire bonding process (e.g. insufficient adhesion, broken wire or impaired reliability) will be obviated. Moreover, since the second electrically-conductive structure 30 is not attached on the sidewall of the LED chip 26, the light extraction efficiency of the LED chip 26 is not adversely affected. In addition, since the LED chip 26 is accommodated within the concave structure 33, the concave structure 33 is helpful to reflect the light so that the light extraction efficiency of the LED chip 26 is enhanced.

It is noted that numerous modifications of the LED package structure of FIG. 7S may be made. For example, like the LED package structure of FIG. 5, the light conversion layer 31 can be formed on the top surface and sidewalls of the LED chip 26. Alternatively, like the LED package structure of FIG. 6, the LED chip 26 is a vertical type LED chip.

In the above embodiment as shown in FIG. 7, the supporting substrate 20 has a single concave structure. Alternatively, the supporting substrate 20 can have plural concave structures for accommodating plural LED chips.

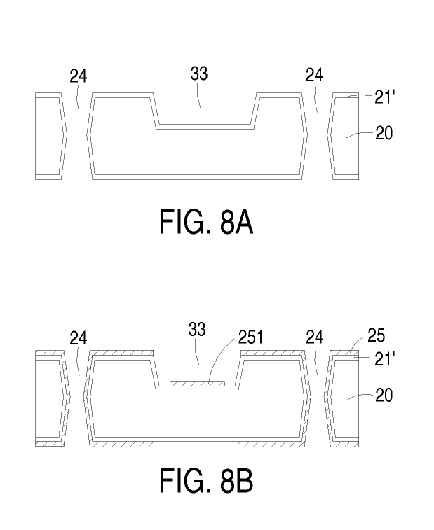

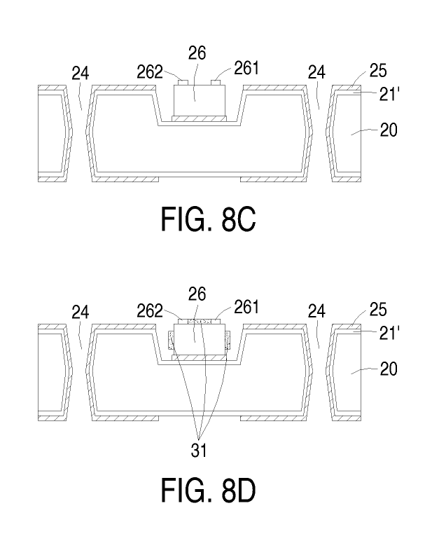

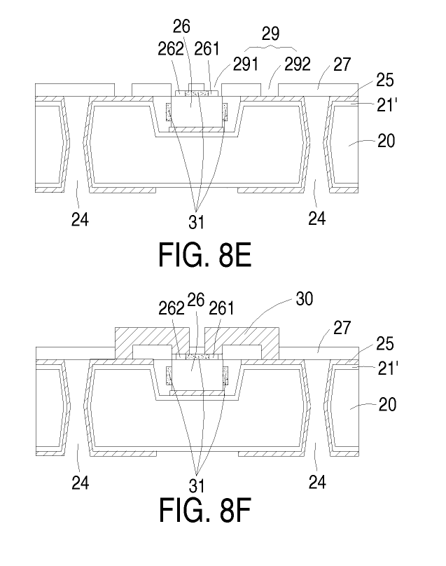

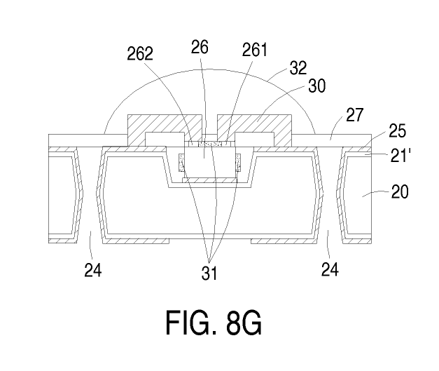

FIGS. 8A˜8G schematically illustrate a method of manufacturing a LED package structure according to a third embodiment of the present invention. The configuration of the resulting LED package structure is shown in FIG. 8G. Similar to FIG. 7K, a supporting substrate 20 having a concave structure 33 and a first channel 24 is shown in FIG. 8A. The way of forming the concave structure 33 and the first channel 24 are similar to those illustrated in FIGS. 7A˜7J, and are not redundantly described herein. In this embodiment, the concave structure 33 is relatively deeper for accommodating the whole LED chip 26 in the sequent steps.

Then, as shown in FIG. 8B, a first electrically-conductive structure 25 is formed on the surface of the first channel 24 and partially formed on the top surface 201 and the bottom surface 202 of the supporting substrate 20, and a metallic base layer 251 for sequent die-bonding process is formed on the bottom surface of the concave structure 33. The first electrically-conductive structure 25 is made of electrically-conductive material (e.g. metallic material) for electrically connecting the top surface 201 of the supporting substrate 20 with the bottom surface 202 of the supporting substrate 20. For producing the first electrically-conductive structure 25, a metallic film layer is firstly deposited on the surfaces of the supporting substrate 20 and the first channel 24 by an electroplating process, an electroless plating process, an E-gun evaporation process or a sputtering process, then a photoresist layer is formed on the metallic film layer, and then a photolithography process is performed to form a pattern in the photoresist layer. After the undesired metal is removed by a wet etching process or a dry etching process, the first electrically-conductive structure 25 as shown in FIG. 8B is formed.

It is noted that the way of forming the first electrically-conductive structure 25 may be modified. For example, a photoresist layer is firstly formed on the supporting substrate 20, and then a photolithography process is performed to form a pattern in the photoresist layer. Then, a metallic film layer is deposited on the photoresist layer by an electroplating process, an electroless plating process, an E-gun evaporation process or a sputtering process. After the photoresist layer is removed, the metallic film layer on the photoresist layer is also stripped, and thus the first electrically-conductive structure 25 as shown in FIG. 8B is formed.

In some embodiments, like FIG. 2L, the first electrically-conductive structure 25 may be filled in the first channel 24 in order to electrically connect the top surface 201 and the bottom surface 202 of the supporting substrate 20.

Next, a die-bonding process is performed to place and fix the LED chip 26 within the concave structure 33 of the supporting substrate 20 (see FIG. 8C). In this embodiment, the LED chip 26 includes electrodes 261 and 262. The LED chip 26 can emit light whose wavelength is ranged from 200 nm to 800 nm. The number of the LED chips 26 can be varied according to the practical requirements. For providing a good bonding strength, the LED chip 26 is die-bonded within the concave structure 33 through silver paste, solder paste, polymeric material or silicone, or by a eutectic bonding process.

Then, as shown in FIG. 8D, a light conversion layer 31 is formed on the top surface and sidewalls of the LED chip 26 for modulating the wavelength of the light emitted from the LED chip 26, thereby producing mixed light. An example of the light conversion layer 31 is a phosphor powder layer, a semiconductor quantum well or a quantum dot layer. The light conversion layer 31 can be formed by a dispensing process or a spraying process.

Then, an insulating layer 27 is formed over the supporting substrate 20 and the LED chip 26. In addition, some perforations corresponding to the electrodes 261 and 262 of the LED chip 26 and the first electrically-conductive structure 25 are created, thereby forming second channels 291 and 292 (as shown in FIG. 8E). The insulating layer 27 is formed by a dry film process. That is, the insulating layer 27 is a dry film. The insulating layer 27 is not formed within the concave structure 33 and on the sidewall of the LED chip 26. An example of the insulating layer 27 is made of silicon dioxide, photoresist, polymeric material, silicone, benzocyclobutene or epoxy resin. In this embodiment, the second channels 291 and 292 are produced by a photolithography process, a wet etching process, a dry etching process, a laser drilling process or a mechanical drilling process. Alternatively, the space between the LED chip 26 and the concave structure 33 can be selectively filled with the insulating material.

Then, as shown in FIG. 8F, a second electrically-conductive structure 30 is filled in the second channels 291 and 292 and partially formed on the insulating layer 27. The second electrically-conductive structure 30 is connected with the electrodes 261 and 262 of the LED chip 26 and the first electrically-conductive structure 25. The second electrically-conductive structure 30 is made of electrically-conductive material (e.g. metallic material) for electrically connecting the electrodes 261 and 262 with the top surface 201 of the supporting substrate 20. In addition, the second electrically-conductive structure 30 is formed by an E-gun evaporation process or a sputtering process with the cooperation of a shield mask.

It is noted that the way of forming the second electrically-conductive structure 30 may be modified. For example, a photoresist layer is firstly formed on the insulating layer 27, and then a photolithography process is performed to form a pattern in the photoresist layer. Then, a metallic film layer is deposited on the photoresist layer by an electroplating process, an electroless plating process, an E-gun evaporation process or a sputtering process. After the photoresist layer is removed, the second electrically-conductive structure 30 as shown in FIG. 8F is formed.

Afterward, as shown in FIG. 8G, a light-transmissible member 32 is formed over the LED chip 26 and the second electrically-conductive structure 30. In this embodiment, the light-transmissible member 32 is a patterned encapsulant member for covering and protecting the LED chip 26 from moisture and foreign article. In addition, the light-transmissible member 32 may be used for increasing the luminance and changing the light profile. The light-transmissible member 32 is made of silicone, polymeric material, epoxy resin, silicon dioxide or glass. The light-transmissible member 32 has a semi-spherical, a cylindrical shape or any other shape. In addition, the surface of the light-transmissible member 32 is curvy, planar or concave.

The light-transmissible member 32 may be produced by molding silicone, polymeric material, epoxy resin, silicon dioxide or glass, or dispensing silicone, polymeric material, epoxy resin, silicon dioxide or glass. Optionally, a barrier layer is formed on the periphery of the LED package structure before the light-transmissible member 32 is produced, and then the light-transmissible member 32 is formed between the barrier layer and the LED package structure by a molding process or a dispensing process.

In the above embodiment, the light conversion layer 31 is formed on the top surface and sidewalls of the LED chip 26. Alternatively, the light conversion layer 31 can be formed on the surface of the light-transmissible member 32 or formed in the light-transmissible member 32. For example, after phosphor powder is added to the host material of the light-transmissible member 32, the light-transmissible member 32 with the function of the light conversion layer is formed in the LED package structure.

From the above discussion, the LED package structure of the first embodiment includes a supporting substrate 20, a first electrically-conductive structure 25, a LED chip 26, an insulating layer 27, a second electrically-conductive structure 30 and a light-transmissible member 32 (see FIG. 8G). The supporting substrate 20 has a first channel 24 (see FIG. 8A). The first electrically-conductive structure 25 is formed on the surface of the first channel 24 and partially formed on the top surface 201 and the bottom surface 202 of the supporting substrate 20. The LED chip 26 is accommodated within the concave structure 33 of the supporting substrate 20. The insulating layer 27 is formed over the supporting substrate 20 and the LED chip 26. In addition, second channels 291 and 292 are formed in the insulating layer 27 corresponding to the electrodes 261 and 262 of the LED chip 26 and the first electrically-conductive structure 25 (see FIG. 8E). The second electrically-conductive structure 30 is filled in the second channels 291 and 292 and partially formed on the insulating layer 27. The second electrically-conductive structure 30 is connected with the electrodes 261 and 262 of the LED chip 26 and the first electrically-conductive structure 25. Through the first electrically-conductive structure 25 and the second electrically-conductive structure 30, the LED chip 26 and the top surface 201 and the bottom surface 202 of the supporting substrate 20 are electrically connected with each other. The light-transmissible member 32 is formed over the LED chip 26 and the second electrically-conductive structure 30 for covering and protecting the LED chip 26.

In the embodiment of FIG. 8, the electrodes 261 and 262 of the LED chip 26 and the top surface 201 of the supporting substrate 20 are electrically connected with each other by an overlay technique. The insulating layer 27 is formed over the supporting substrate 20 and the LED chip 26 by a dry film process. The second channel 29 is formed in the insulating layer 27, and the second electrically-conductive structure 30 is formed in the second channel 29. The second electrically-conductive structure 30 is connected with the electrodes 261 and 262 of the LED chip 26 and the top surface of the supporting substrate 20. In comparison to the conventional wire bonding process, the electrically-conductive structure produced by the wireless interconnection process is thicker and more reliable, and capable of withstanding higher mechanical stress. Consequently, the drawbacks encountered from the conventional wire bonding process (e.g. insufficient adhesion, broken wire or impaired reliability) will be obviated. Moreover, since the second electrically-conductive structure 30 is not attached on the sidewall of the LED chip 26, the light extraction efficiency of the LED chip 26 is not adversely affected.

It is noted that numerous modifications of the LED package structure of FIG. 8G may be made. For example, like the LED package structure of FIG. 6, the LED chip 26 is a vertical type LED chip.

Moreover, in the LED package structure of FIG. 8G the first electrically-conductive structure 25 is not completely filled in the first channel 24. Consequently, the first channel 24 can be used as a dicing line. After the LED package structure is produced in a batch, the LED package structure can be cut along the first channels 24, thereby acquiring plural LED package structure unit. In other words, the first channel 24 has the functions of using as the dicing line and the electrical connection medium.

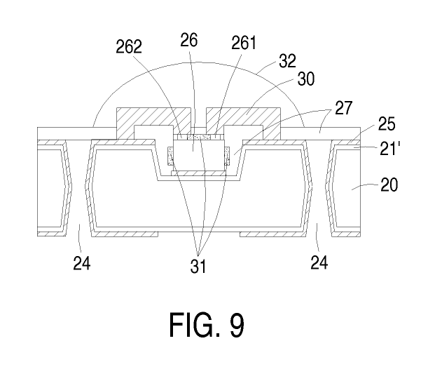

FIG. 9 is a schematic cross-sectional view illustrating a variation example of the LED package structure of FIG. 8G. In comparison with FIG. 8G, the insulating layer 27 is further formed within the concave structure 33. That is, the space between the LED chip 26 and the concave structure 33 is filled with the insulating material.

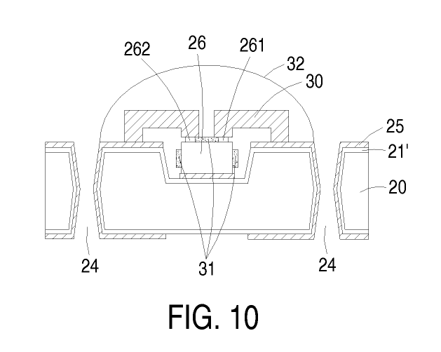

FIG. 10 is a schematic cross-sectional view illustrating another variation example of the LED package structure of FIG. 8G. After the second electrically-conductive structure 30 is formed, the insulating layer 27 is removed by a dry etching process (e.g. a plasma etching process using oxygen, nitrogen or argon as an etchant) or a wet etching process. Then, a light-transmissible member 32 is formed over the LED chip 26 and the second electrically-conductive structure 30.

From the above description, in the LED package structure and the manufacturing process of the present invention, the electrodes of the LED chip and the top surface of the supporting substrate are electrically connected with each other by an overlay technique. In comparison to the conventional wire bonding process, the electrically-conductive structure produced by the wireless interconnection process is thicker and more reliable, and capable of withstanding higher mechanical stress. Consequently, the drawbacks encountered from the conventional wire bonding process (e.g. insufficient adhesion, or impaired reliability) will be obviated. Moreover, in comparison with the surface of the conventional metallic lead frame or circuit board, the surface of the silicon wafer of the present invention is smoother and suitable for performing a eutectic bonding process. In addition, the silicon wafer has some additional benefits such as high thermal conductivity, high melting point and low mechanical stress. The LED package structure of the present invention has reduced layout area so that the manufacturing process of the present invention is advantage for producing LED package structure in a batchwise manner.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A LED package structure, comprising:
a supporting substrate comprising a top surface, a bottom surface and at least one first channel;
at least one first electrically-conductive structure filled in said first channel and partially formed on said top surface and said bottom surface of said supporting substrate;
a LED chip disposed over said supporting substrate;
an insulating layer formed over said supporting substrate and on bilateral sides of said LED chip, wherein said insulating layer has at least one second channel corresponding to said first electrically-conductive structure; and
at least one second electrically-conductive structure filled in said second channel and partially formed on said insulating layer, and connected with an electrode of said LED chip, wherein said LED chip and said top surface and said bottom surface of said supporting substrate are electrically connected with each other through said first electrically-conductive structure and said second electrically-conductive structure.

2. The LED package structure according to claim 1, wherein said supporting substrate further comprises a concave structure, and said LED chip is accommodated within said concave structure.

3. The LED package structure according to claim 1, wherein said insulating layer and said LED chip are substantially coplanar.

4. The LED package structure according to claim 1, further comprising a light conversion layer formed on a top surface of said LED chip or on said top surface and sidewalls of said LED chip.

5. The LED package structure according to claim 1, further comprising a light-transmissible member formed over said LED chip and said second electrically-conductive structure.

6. The LED package structure according to claim 5, further comprising a light conversion layer formed on a surface of said light-transmissible member or in said light-transmissible member.

7. The LED package structure according to claim 5, wherein said light-transmissible member comprises silicone, polymeric material, epoxy resin, silicon dioxide or glass.

8. The LED package structure according to claim 1, wherein said supporting substrate is a silicon wafer, a ceramic substrate, a sapphire substrate, a metallic substrate, a glass substrate or a plastic substrate.

9. The LED package structure according to claim 1, wherein said insulating layer comprises silicon dioxide, polymeric material, silicone, photoresist, benzocyclobutene or epoxy resin.

10. A LED package structure, comprising:
a supporting substrate having a top surface and a bottom surface, wherein said supporting substrate comprises a first channel and a concave structure;
at least one first electrically-conductive structure filled in said first channel and partially formed on said top surface and said bottom surface of said supporting substrate;
a LED chip accommodated within said concave structure;
an insulating layer formed over said supporting substrate and said LED chip and having at least two second channels, wherein said second channels are corresponding to an electrode of said LED chip and said first electrically-conductive structure, respectively; and
at least one second electrically-conductive structure filled in said second channels and partially formed on said insulating layer, and connected with said electrode of said LED chip and said first electrically-conductive structure, wherein said LED chip and said top surface and said bottom surface of said supporting substrate are electrically connected with each other through said first electrically-conductive structure and said second electrically-conductive structure.

11. The LED package structure according to claim 10, wherein said insulating layer is a dry film, and said insulating layer is not formed within said concave structure and on a sidewall of said LED chip.

12. The LED package structure according to claim 10, wherein said insulating layer is further formed within said concave structure.

13. The LED package structure according to claim 10, wherein said first channel is further used as a dicing line.

14. A LED packaging method, comprising steps of:
providing a supporting substrate comprising a top surface and a bottom surface;
forming at least one first channel in said supporting substrate;
forming at least one first electrically-conductive structure in said first channel and partially on said top surface and said bottom surface of said supporting substrate so as to electrically connect said top surface and said bottom surface of said supporting substrate;
disposing a LED chip over said supporting substrate;
forming an insulating layer over said supporting substrate and on bilateral sides of said LED chip, wherein said insulating layer has at least one second channel corresponding to said first electrically-conductive structure; and
forming at least one second electrically-conductive structure in said second channel and partially on said insulating layer so as to connect with an electrode of said LED chip, wherein said LED chip and said top surface of said supporting substrate are electrically connected with each other through said second electrically-conductive structure.

15. The LED package method according to claim 14, further comprising a step of forming a concave structure in said supporting substrate, wherein said LED chip is accommodated within said concave structure.

16. The LED package method according to claim 14, wherein said insulating layer and said LED chip are substantially coplanar.

17. The LED package method according to claim 14, wherein said insulating layer is a planarization structure formed by capillary injection, vacuum suction or stencil printing.

18. The LED package method according to claim 14, wherein said LED chip is die-bonded on said supporting substrate by eutectic bonding process, silver paste, solder paste, polymeric material or silicone.

19. The LED package method according to claim 14, further comprising a step of forming a light-transmissible member over said LED chip and said second electrically-conductive structure.

20. The LED package method according to claim 19, further comprising a step of forming a light conversion layer on a surface of said light-transmissible member or in said light-transmissible member.

21. The LED package method according to claim 14, further comprising a step of forming a light conversion layer on a top surface of said LED chip or on said top surface and sidewalls of said LED chip.

22. A LED packaging method, comprising steps of:
providing a supporting substrate comprising a top surface and a bottom surface;
forming at least one first channel and a concave structure in said supporting substrate;
forming at least one first electrically-conductive structure in said first channel and partially on said top surface and said bottom surface of said supporting substrate so as to electrically connect said top surface and said bottom surface of said supporting substrate;
disposing a LED chip within said concave structure of said supporting substrate;
forming an insulating layer over said supporting substrate and said LED chip and forming at least two second channels in said insulating layer, wherein each said second channel is corresponding to an electrode of said LED chip and said first electrically-conductive structure; and
forming at least one second electrically-conductive structure in said second channels and partially on said insulating layer so as to connect with said electrode of said LED chip and said first electrically-conductive structure.

23. The LED package method according to claim 22, wherein said first electrically-conductive structure is a film layer formed on the surface of said first channel.

24. The LED package method according to claim 22, wherein said insulating layer is a dry film, and said insulating layer is not formed within said concave structure and on a sidewall of said LED chip.

25. The LED package method according to claim 22, wherein said insulating layer is further formed within said concave structure.

26. The LED package method according to claim 22, further comprising a step of removing said insulating layer.
